(19) United States
(12) Patent Application Publication
(10) Pub. No.: US 2025/0168522 A1
(43) Pub. Date: May 22, 2025

(54) METHOD AND IMAGE PROCESSOR UNIT FOR PROCESSING IMAGE DATA

(71) Applicant: Dream CHIP Technologies GmbH, Garbsen (DE)

(72) Inventor: Noha EL-YAMANY, Garbsen (DE)

(73) Assignee: Dream CHIP Technologies GmbH, Garbsen (DE)

(21) Appl. No.: 18/841,817

(22) PCT Filed: Jan. 19, 2023
(86) PCT No.: PCT/EP2023/051242

§ 371 Date: Aug. 27, 2024

(51) Int. Cl. H04N 23/88; H04N 23/84; H04N 25/60

(52) U.S. Cl. CPC H04N 23/88; H04N 23/843; H04N 25/60

(57) ABSTRACT

The disclosed invention relates to a method for processing image data of an image sensor comprising a matrix of light sensitive elements and a plurality of lens elements and/or filter elements arranged in a pixel matrix in front of a finer sub-pixel matrix of light sensitive elements. A group of light sensitive elements are placed behind a common lens element and/or a common filter element to provide sub-pixel values for a respective position in the pixel matrix. Said image sensor is adapted to capture image data for a plurality of views, wherein each view comprising a matrix of a selected group of sub-pixel values of the pixel matrices captured by the matrix of light sensitive elements.

According to the invention, for each captured view of the image, first variations of sub-pixel values in the respective view are determined separately from other views of the same image. Second variations of sub-pixel values related to the same position in the pixel matrix behind a respective lens element and/or filter element are determined in a set of views of the same image. The image data for the image are processed by use of the determined first and second variations.

### FIELD OF THE INVENTION

The invention relates to a method for processing image data of an image sensor, wherein the image sensor a matrix of light sensitive elements and a plurality of lens elements and/or filter elements arranged in a pixel matrix in front of a finer sub-pixel matrix of light sensitive elements, wherein a group of light sensitive elements are placed behind a common lens element and/or a common filter element to provide sub-pixel values for a respective position in the pixel matrix and wherein said image sensor (4) is adapted to capture image data for a plurality of views, wherein each view comprising a matrix of a selected group of sub-pixel values of the pixel matrices captured by the matrix of light sensitive elements.

The invention further relates to an image processor unit for processing image data provided by an image sensor, said image sensor including a matrix of light sensitive elements and a plurality of lens elements and/or filter elements arranged in a pixel matrix in front of a finer sub-pixel matrix of light sensitive elements, wherein a group of light sensitive elements are placed behind a common lens element and/or a common filter element to provide sub-pixel values for a respective position in the pixel matrix. Said raw image data comprising a matrix of pixel values for the pixel matrix captured by the matrix of light sensitive elements, said matrix of pixel values being divided in a set of views, each view comprising a matrix of sub-pixel values comprising a view specific sub-pixel of the sub-pixel matrix for each position in the matrix, which is related to a respective lens element and/or filter element.

The invention further relates to a computer program comprising instructions which, when the program is executed by a processing unit causes a processing unit to carry out the steps of the above referenced method.

### BACKGROUND OF THE INVENTION

Digital imagers are widely used in everyday products such as smartphones, tablets, notebooks, cameras, cars and valuables. Many of the imaging units in those products have the feature of automatic focusing in order to produce sharp images or sharp videos.

Traditionally, automatic focusing is control based on a detecting of the contrast, wherein the lens is mechanically moved to the position where the scene contrast is the highest. This control process is generally slow and requires a lens mechanics for mechanically varying the position of the lens.

The speed of automatic focusing and the accuracy of focusing can be improved with the technology of phase detecting automatic focusing (PDAF) using PDAF sensors or focus sensors comprising the so-called phase detection (PD) pixels which are located separately and regularly across the whole image sensor area. The phase information (disparity) estimated from the phase detection pixels is used to determine the lens position in order to achieve optimal focus in a pre-defined region of interest (ROI) in the scene. This process is typically very fast, if the disparity is accurate enough.

Omnidirectional focus sensors based, for example, on the on-chip-lens (OCL) technology, allows to use all the image pixels for phase detection in order to improve the accuracy and speed of automatic focusing.

R. Garg, N. Wadhwa, S. Ansari and Y. T. Barron: “Learning Single Camera Depth Estimation Using Dual Pixels”, in: Proceedings of the IEEE International Conference on Computer Vision and Pattern Recognition, 2019, pp. 1556-1565 describes a learning based method to work on dual-pixel imagery to estimate depth up to an inherent ambiguity in the depth estimated from dual-pixel use.

N. Wadhwa, R. Garg, D. E. Jacobs, B. E. Feldman, N. Kanazawa, R. Carroll, Y. Movshovitz-Attias, J. T. Barron, Y. Pritch, M. Levoy: Synthetic Depth-of-Field with a Single-Camera Mobile Phone”, in: ACM Trans. Graph., vol. 37, no. 4, art. 64, pp. 64:1-64:13 describes a system to compute synthetic shallow depth-of-field images on mobile phones by use of dual-pixel sensors per lens element. A neural network trained to segment out people and the accessories is combined with a sensor with dual-pixel (DP) autofocus hardware, which provides a two-sample light field with a narrow base line to extract dens depth maps.

Y. Zhang, N. Wadhwa, R. S. S. Orts-Escolano, C. Haene, S. Fanello, R. Garg: Du² Net: Learning Depth Estimation from Dual-Cameras and Dual-Pixels, in: Computer Vision, ECCV 2020, eds.: A. Vedaldi, H. Bischof, T. Brox, J.-M. Frahm, Springer International Publishing, Cham 2020, pp. 582-598 describes the use of neural networks for depth estimation that combines stereo from dual cameras with stereo from dual-pixel sensor to provide a dens depth map with sharp edges.

A. Abuolaim, M. S. Brown: “Defocus Deblurring Using Dual-Pixel Data”, in: European Conference on Computer Vision 2020, pp. 110-126 address a problem of defocus blur arising in images that are captured with a shallow depth of field due to the use of a wide aperture. The proposed method makes use of dual-pixel sensors capturing two sub-aperture use of the scene in a single image shot. The two sub-aperture images are used to calculate the appropriate lens position to focus on a particular scene region and are discarded afterwards. A deep neural network architecture uses the discarded sub-aperture images to reduce defocus blur.

S. Woo, Y. H. Ryu, Y. O. Kim: “Ghost Free Deep High-Dynamic Range Imaging Using Focus Pixels for Complex Motion Scenes”, in: IEEE Transactions on Image Processing, vol. 30, pp. 5001-5016 discloses a deep learning technique for a seamless fusion of multi-exposed low dynamic range images using a focus-pixel sensor providing a left and right luminance images simultaneously with full resolution RGB image.

WO 2020/237366 A1 discloses a system and method for reflection removal of an image from a dual-pixel sensor by determining a first radiant of the left view and a second radiant of the right view and determining disparity between the gradients. Confidence values and a weighted gradient map is determined to achieve a background layer and a reflection layer after iteratively minimising cost function.

This method is described in more detail in A. Punnappuarath, M. S. Brown: “Reflection Removal Using a Dual-Pixel Sensor”, in: Proceedings of the IEEE International Conference on Computer Vision and Pattern Recognition 2019, pp. 7628-7637.

S. M. Woo, Y. W. Ha, Y. O. Kim: “Super-Resolution Imaging Using a Focus Pixel Sensor”, in: IEEE Asia Pacific Signal and Information Processing Association Annual Summit and Conference (APSIPA-ASC), Japan 2021 describes infusion of multiple-low resolution focus pixel images with a normal image based on repetitive channel and spatial tension layer structures.

G. Chataignier, B. Vandame, J. Vaillant: “Joint Electromagnetic and Ray-Tracing Simulations for Quad-Pixel Sensor and Computational Imaging”, in: Optics Express, vol. 27, no. 21, 14 Oct. 2019, pp. 3046-3051 describes a design for quad-pixel sensors where a micro-lens covers 2×2 sub-pixels and a method for mixing wave optic simulations with ray tracing simulation in order to generate physically accurate synthetic images.

### SUMMARY OF THE INVENTION

According to one aspect of the invention, a plurality of views are captured for each image, wherein each view comprises a matrix of a selected group of sub-pixel values of the pixel matrix captured for the image by the matrix of light sensitive elements. Thus, for a respective pixel position related to a common lens element and/or filter element, the plurality of finer sub-pixel values are assigned to and distributed over the set of views. Each view represents at least one of these finer sub-pixel values, but not all of the sub-pixel values for a pixel position, wherein the combined views together contain all information of the sub-pixel values for each pixel position. These multi-views of an image allows to determine different variations caused by a plurality of effects, e.g., crosstalk and shading effects arising from the common main lens and variations in sensitivity, brightness, exposure time related to the common lens element and/or filter element of the pixel position of the related set of sub-pixels.

A method in accordance with the present invention includes:
for each captured view of the image, determining first variations of sub-pixel values in the respective view separately from other views of the same image;
determining second variations of sub-pixel values related to the same position in the pixel matrix behind a respective lens element (7) and/or filter element (9) in a set of views of the same image;
processing the image data for the image by use of the determined first and second variations.

The variations of the sub-pixel values can be specified by use of operators to determine different types of effects when capturing an image with sub-pixel values. The sub pixel of a common pixel position related to a common lens element (e.g. On-Chip-Lens) and/or filter element does not behave similar. They can vary in sensitivity and brightness. Brightness variation may also occur due to shading from the common main lens. Further, crosstalk may occur between light sensitive elements and their related sub-pixel values. The exposure time has also an effect to the sub-pixel values. These effects can be assigned to a set of operators, wherein each of the operator is related to either the first variations of sub-pixel values in the respective view separately from other views of the same image or to the second variations of sub-pixel values related to the same position in the pixel matrix in a set of views of the same image.

The operations on the captured raw image data can be automatically performed by use of a generic image formation model which expresses the number n-th view image. This generic image formation model can be established by the relations:

$${Y}_{n} = {F}_{n} ( {S}_{n} X ⊗ {H}_{n} ( D ) ) + {η}_{n} , with n = 1 , 2 , … , N ;$$

$$and$$

$${Y}_{n} = {E}_{n , m} {C}_{n , m} {Y}_{m} , with n = 1 , 2 , … , N , m \neq n ;$$

where Yₙ is the n-th view image pixel matrix, Fₙ is a colour-filter-array sub-sampling operator associated with the n-th view image pixel matrix, Sₙ is a spatially-variant and colour-dependent lens shading operator for the n-th view image pixel matrix, X denotes an unknown scene region of interest (ROI) with a focal depth (D), ⊗ denotes a two-dimensional convolution operation, Hₙ(D) is a point spread function associated with the n-th view image pixel matrix at a constant focal depth (D), ηₙ is a signal-dependent noise for the n-th view pixel matrix, E_{n,m} is a colour-dependent exposure variation operator between the n-th and m-th view image pixel matrix, and C_{n,m} is a wavelength and colour-dependent crosstalk operator between the n-th and m-th view image pixel matrix, wherein C_{n,m} captures the wavelength and colour-dependent crosstalk between the sub-pixels of a common position in the pixel matrix sharing the same lens element and/or filter element.

Processing the image data captured i.e. by an On-Chip-Lens all-focus sensor by use of the above mentioned image formation model is very effective and allows the consideration of a plurality of the characteristics of the image sensor by correlating the different matrices, operators and factors.

The processing of the image data of an image sensor can have the steps of:
Combining a set of views of an image by combining the plurality of sub-pixel values related to a common position in the pixel matrix, respectively, for each position in the matrix and pre-processing the combined sub-pixel values of the captured pixel matrix for an image;
separately pre-processing the views by pre-processing the captured pixel matrix with the plurality of sub-pixel values of a respective view by evaluating the variations between the sub-pixel values related to the same position in the matrix; and
joined pre-processing of both the pre-processed combined pixel values of the captured pixel matrix in the set of views and the pre-processed pixel matrix of the plurality of sub-pixel values for each position in the matrix for each view by use of the result of the evaluation of the variations.

Combining the plurality of sub-pixel values results in a binning of the image data. This allows to determine variations between these binned image data for an image and the image data in at least one view of this image.

The processing of views of the image by use of the determined variations, which are described by operators of the image formation model, allows separately pre-processing both the combined views of an image, i.e. the pixel matrixes comprising the combined pixel values, and the separate views of the image, i.e. the pixel matrixes comprising the separate sub-pixel values. This provides an improved and image processing flow which makes use of the characteristics of on-chip-lens all-focus sensors.

The method leverages all the image information captured by e.g. an OCL-all-focus sensor, without discarding the results after calculating disparities.

The plurality of sub-pixel values related to a common pixel position in the set of views can be combined, for example, by automated processing the sum of the sub-pixel values related to the same position in the matrix to achieve a combined view comprising a sum-binned pixel matrix. Thus, the sub-pixel values captured by the light sensitive elements positioned under e.g. a common lens element and/or a common filter element are combined in a combined view to one combined pixel value by processing the sum of these pixel values.

The plurality of sub-pixel values which are related to a common position in the set of views, can be combined by automatic processing the average of the sub-pixel values related to the same pixel position in the set of views to achieve an average pixel matrix. Thus, the combined pixel value is processed for one pixel position of the pixel matrix related e.g. to one common lens element and/or one common filter element by calculating the average of the sub-pixel values in the set of views captured by the light sensitive elements position below one common lens element and/or one common filter element.

Thus, the sub-pixel values related to one common pixel position in the pixel matrix are combined to one resulting common summed and/or averaged pixel value for the pixel position in the pixel matrix.

Combining pixel values in a plurality of views of an image has the effect of increasing the brightness compared to the brightness of a single view, i.e. the sub-pixel values captured by only one light sensitive element. The combined pixel matrix reflects an image captured with longer exposure time compared to a pixel matrix comprising only one sub-pixel value captured by one light sensitive element.

The captured views (i.e. captures pixel matrix of an image) which comprises the plurality of sub-pixel values per position in the view can be pre-processed by use of a set of pixel matrixes, wherein each view of the set is a sub-pixel matrix comprising sub-pixel values of a related set of light sensitive elements. Each of these light sensitive elements of the related set have the same relative position in the group of light sensitive elements for a common position in the view related to a common lens element and/or a common filter element. Thus, a group of sub-pixel values forms a view, i.e. a pixel matrix for an image. The sub-pixel values are captured by light sensitive elements each having the same relative position with respect to their related pixel position in the pixel matrix, i.e. the related lens element and/or filter element. For example, when four light sensitive elements are placed below a common pixel position, i.e. lens element and/or filter element, the sub-pixels at the upper left position forms one first pixel matrix, the sub-pixel of the upper right position forms the second pixel matrix, the sub-pixels at the left-down position forms the third pixel matrix and the sub-pixel of the right-down position forms the fourth pixel matrix.

A variation in exposure characteristics can be evaluated by correlating the combined views of an image with at least one view of the image. The combined view which comprises the combined pixel values each processed from the combination of related sub-pixel values for a respective position in the matrix represents a longer exposure time compared to the separate pixel matrices each comprising a matrix of sub-pixel values. Said pixel values are each captured by one respective light sensitive element.

Thus, by, for example comparing the combined pixel values of the combined views with related sub-pixel values of this one of the views of the set can be used to evaluate characteristics of the image related e.g. to an exposure time. For example, the sum-binned pixel matrix provides a set of pixel values captured by at least two of the image sensitive elements at pixel positions in the pixel matrix is brighter, i.e. has the summed-up increased pixel value. The pixel matrix comprising one sub-pixel value for a pixel position provides an image having a characteristic like a shorter exposure time, i.e. only the smaller single pixel value, than the larger sum-binned pixel value. The difference of the pixel values related to a common pixel position in the pixel matrix is a valuable information.

A view blur can be evaluated by correlating related sub-pixel values of at least two views of the image. A first sub-pixel matrix of a first group of sub-pixel values can be correlated with a second sub-pixel matrix of a second group of sub-pixel values.

Because the scene is optically blurred based on the distance from the focal plane there is a shift on disparity between the number N of sub-aperture (focus) views. This disparity depends on the depth at the shape of the blur. The disparity between number of N views can be modelled as explicit shift in the image content with sub-pixel accuracy. When the sub-pixel sharing one common pixel position in the pixel matrix, i.e. common On-Chip-Lenses and/or filter elements, have the same exposure, the shift estimation can be simplified. Due to the split-pixel arrangements, the disparity is directional, having a certain direction for a certain view. This allows a more simple estimation of the shift, as a surge direction is known.

The sub-pixel matrices can be correlated with each other by automatically processing the difference values for each of the positions in the matrix as difference of the sub-pixel value of one sub-pixel matrix of the set of the sub-pixel matrices and the sub-pixel values of another sub-pixel matrix of the same set of sub-pixel matrices.

Thus, for each pixel position in the view, i.e. the related pixel matrix, at least one difference value is processed from sub-pixel values related to the same pixel position, i.e. common lens elements and/or filter elements. The resulting at least one pixel matrix comprising the resulting different values for each related pixel position can be stored and used for further processing of the image data to achieve an improved pre-processed image of sequence of images.

A disparity between the views of an image captured by the image sensor can be automatically estimated, wherein the disparity of sub-pixel values related to the same pixel position is determined.

Thus, the sub-pixel values related to a different relative positions in a common pixel position of the pixel matrix, i.e. in different relative positions related to a common lens element and/or filter element, are correlated with each other in order to find disparities.

Depth values of the captured image representing the focal depth of the captured image related to a focal plane of the image sensor can be automatically estimated.

The depth values can be achieved from the differences of the sub-pixel values for one common pixel position in the pixel matrix. i.e. differences between the set of sub-pixels which are related to a common lens element and/or filter element due to the relative displacement of the image sensor elements below the common lens element and/or filter element.

The method can be implemented as a routine in an image processor unit. i.e. by respective programming a processor, or by providing an image processor unit with appropriate hardware logic to perform the above mentioned method steps. Thus, the image processor unit can be implemented as programmed microcontroller, microprocessor, or in form of a specialized hard- und software logic, e.g. ASIC, or as hardware logic, e.g. FPGA.

### BRIEF DESCRIPTION OF THE DRAWINGS

The invention is further described by a way of an example with the enclosed drawings. It shows:

FIG. 1—Block diagram of an image camera comprising an image sensor and an image processor unit;

FIG. 2—Flow diagram of an embodiment of the method for processing image data;

FIG. 3—Flow diagram of an exemplary second part of the method for processing image data;

FIG. 4—Schematic pixel matrix captured by an image sensor and related set of pixel matrices process from the captured pixel matrix;

FIG. 5—Diagram of the focus effect with an on-chip-lens sensor depending on the focal plane;

FIG. 6—Flow diagram of an exemplary method for processing image data;

FIG. 7—Flow diagram of an exemplary method for constrained block matching.

### DETAILED DESCRIPTION OF THE INVENTION

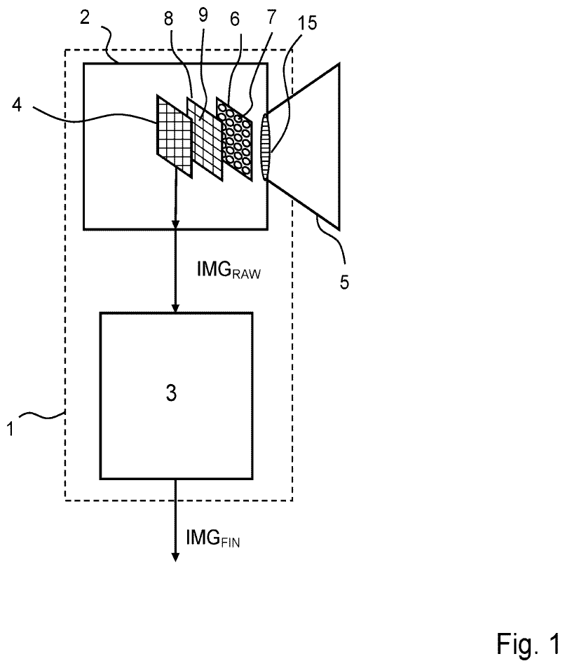

FIG. 1 presents an exemplary schematic block diagram of an image processor unit 1 comprising a camera 2 and an image processor unit 3 for processing raw image data IMG_{RAW} provided by an image sensor 4 of the camera 2.

The image sensor 4 comprises an array of pixels P_{x,y}, i.e. pixel matrix, so that the raw image IMG_{RAW} is the data set provided by the matrix of pixels per image.

The camera 2 comprises an opto-mechanical lens system 5, e.g. a fixed uncontrolled lens 15 or a variable controllable lens system.

A group of light sensitive elements of the image sensor 4 is placed behind a common lens element 7. Thus, the light passing through one lens element 7 of the lens matrix 6 reaches the at least two light sensitive elements related to that lens elements 7. For example, the group of light-sensitive elements can be a group of two elements placed in horizontal direction adjacent to each other, or a group of four light sensitive elements placed with two rows and two columns behind the common lens elements 7.

In order to capture colours in the image, a colour filter array 8 (CFA) comprising a matrix of filter elements 9 with alternating different filter characteristics (e.g. Bayer RGGB, RGBE, RYYB, CYYM, CYGM, RGBW, RGBW #1 . . . 3, X-Trans, Quad Bayer, RYYB Quad Bayer, Nonacell, RCCC, RCCB etc.) can be (optionally) provided in the optical path in front of the image sensor 4. Preferably, the colour filter array 8 is placed between the lens matrix 6 and the light sensitive elements of the image sensor 4. The colour filter array 8 can also be placed in front of the lens matrix 6, i.e. between the lens system 5 and the lens matrix 6.

The group of light-sensitive elements of the image sensor 4, which are assigned to a common lens element 7, can share a common filter element 9, i.e. the same colour. In another embodiment, each light-sensitive element of the image sensor 4 could also have its specific filter element 9 having the same colour as the filter element 9 of the group assigned to the same lens element 7, or at least in part another colour compared to other light-sensitive elements of the group.

The image processor unit 1 can be incorporated in a handheld device, like a smartphone, a tablet, wearables, a picture or video camera, or the like.

The image processor unit 1 is arranged to process image IMG_{RAW} from the image sensor 4 capturing images, wherein a frame is also considered to be an image in the meaning of the present invention.

The image processor unit 3 can be incorporated into the image camera 2 or provided as a separate unit, which is wired or wirelessly connected to the image camera 2.

The image processor unit 3 is arranged for pre-processing of the raw image data IMG_{RAW} in order to achieve a final image IMG_{FIN}. This also includes the option of receiving a sequence of final images of frames.

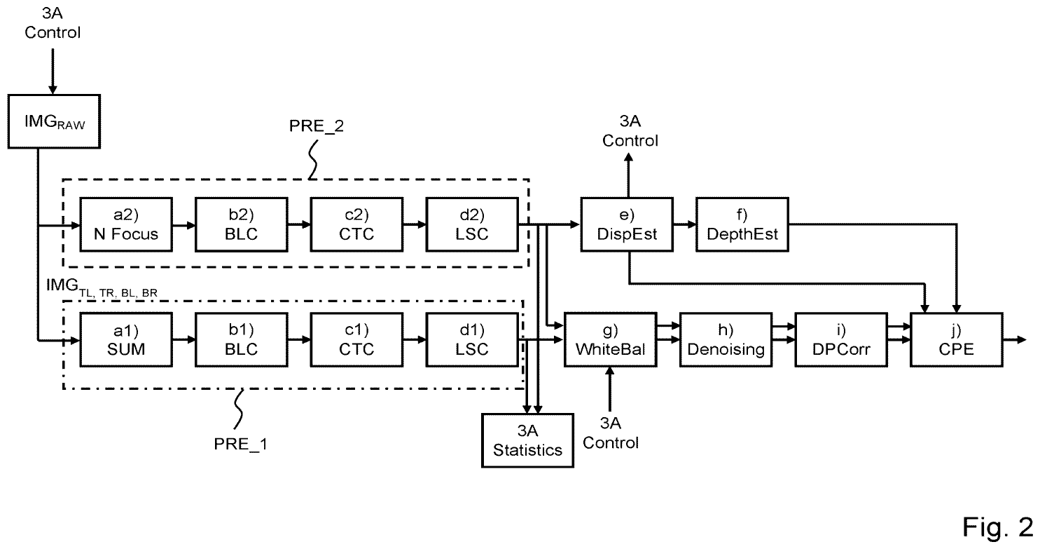

FIG. 2 is an exemplary flow diagram of the method of processing image data IMG_{RAW} captured by the image sensor 4. The image sensor 4, for example a multiple on-chip lens sensor, e.g. a 2×2 OCL sensor captures different information about the scene with the sub-aperture views.

The camera can be 3A-controlled for automatic exposure, automatic balancing and automatic focusing control.

In a first sequence PRE_1, the plurality of sub-pixel values IMG_{TL, TR, BL, BR} related to the composition in the pixel matrix is combined in step a1) to achieve a sum-binned raw image. The sum of the pixel values of the group of light-sensitive elements related to the common lens element 7 is summed up to achieve a resulting summed pixel value for the pixel position in the pixel matrix related to the common lens element 7.

In a second pre-processing flow PRE_2, the multiple number n of pixel values IMG_{TL, TR, BL, BR} captured by the group of light-sensitive elements related to a common lens element 7 is pre-processed separately from each other. Thus, the set of N pixel matrices, each comprising the sub-pixel values of a specific position in the pixel matrix, is pre-processed separately from the combined sum-binned image of step a1) in sequence PRE_1. The captured pixel matrix comprising the plurality of sub-pixel values per position in the pixel matrix is processed by use of a set of pixel matrices in the pre-processing sequence PRE_2 which starts with step a2). Each view captured by the image sensor of the set of views of an image comprises a pixel matrix having a sub-pixel matrix for each pixel position comprising the sub-pixel values captured from a related set of light-sensitive elements. Each light-sensitive element of the related set having the same relative position in the group of light-sensitive elements for a common position in the pixel matrix is related to a common lens element 7 or a common filter element 9.

Both separate sequences PRE_1 and PRE_2 may provide in a step b1) and b2) for example a black level correction of the sum-binned raw images (step b1)) or the N focus images (step b2)).

Further, the flows of pre-processing PRE_1 and PRE_2 each may comprise a step c1) and a step c2) of cross-talk correction of the sum-binned raw image (step c1)) and separately of the N focus images (step c2)).

Further, the separate flows of pre-processing PRE_1 and PRE_2 may comprise a step d1) and d2) of lens shading correction LSC for the sum-binned raw image (step d1) and separately for the N focus images (step d2)).

As a result, statistic control values can be optionally obtained (3A statistics) from the outcome of both the separated sequences of pre-processing. The statistics can be used for the 3A control.

The pre-processing flow PRE_2 of the N focus images IMG_{TL, TR, BL, BR} can be followed up by step e) of disparity estimation. The result of the disparity estimation can be used for the 3A control.

Further, the result can be used for an additional step f) of depth estimation.

Both results of the separate pre-processing PRE_1 and PRE_2 of the sum-binned raw image and the N focus images can be used as input for further pre-processing step g) of white balancing, step h) of raw image denoising, step i) of defect pixel correction and step j) of computational photography engine CPE. This computational photography engine CPE can include at least one of a set of image processing routines based on the result of the separate pre-processing flow and the combined pre-processing flows as well as the result of step e) of disparity estimation DispEst and depth estimation DepthEst.

The white balancing can be further controlled by the 3A control.

In the 3A control, the sensor can be exposed for focus images of the sum-binned image depending on the feature. The exposure variation shift, e.g. log 2(1/N) can be controlled for example between the views and the sum-binned images. A sub-pixel exposure variation is possible. For the step g) of white balancing, the same white balancing can be applied for focus images and sum-binned images, i.e. for the result of both of the separate pre-processing flows.

From uni-directional disparities and multi-directional disparities, auto focus statistics can be achieved.

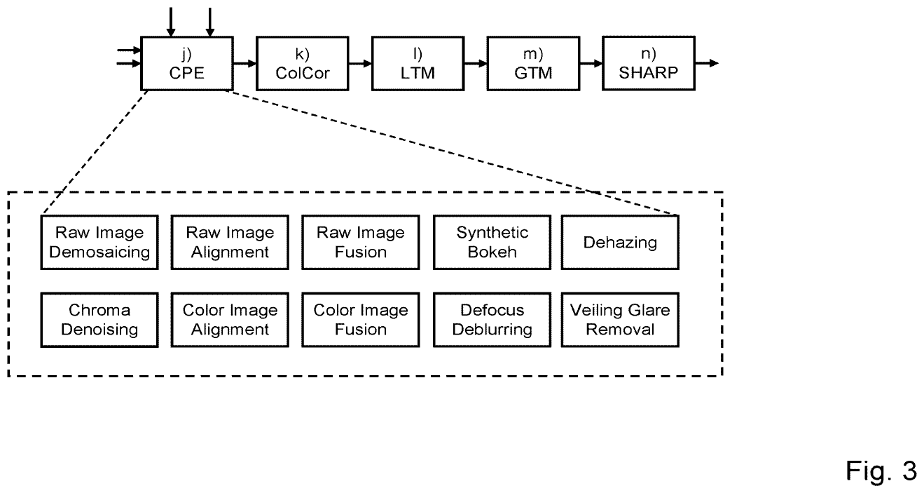

FIG. 3 shows an exemplary flow diagram of the follow up of the flow shown in FIG. 2.

The step j) of computational photography engine CPE may include at least one of the sets of processes:
Raw Image Demosaicing, Raw Image Alignment, Raw Image Fusion, Synthetic Bokeh, Dehazing, Chroma Denoising, Colour Image Alignment, Colour Image Fusion, Defocus Deblurring, Veiling Glare Removal, and the like.

Bokeh is the esthetic quality of the blur produced in out-of-focus parts of the image. Differences in lens aberrations and aperture shape cause very different bokeh effects.

The step j) of computational photography engine can be followed up by a combined post-processing of the image processed in step j) or a sequence of images. These post-processing steps can include step k) of colour correction, step 1) of local tone mapping LTM, step m) of global tone mapping, step n) of sharpening and the like. These post-processing steps can be provided in form of additional separate processing routines of processing units. These post-processing steps could also be part of the computational photography engine CPE.

These pre-processing and post-processing steps of the CPE are, in general, known and now carried out based on the combination of the sub-pixel values of the captured pixel matrix.

The method for processing image data can be based on the computational photography engine having the pre-processed N-focus images and the pre-processed sum-binned images as input pixel matrixes separately from each other. Further, the computational photography engine can also include the estimated disparity and the estimated depth as input. This provides increased image information related to the characteristics of the On-Chip-Lens image sensor.

The computational photography engine can provide a full-colour image at the output having a superior quality, a high-dynamic range, a high-resolution and already being denoised and sharpened.

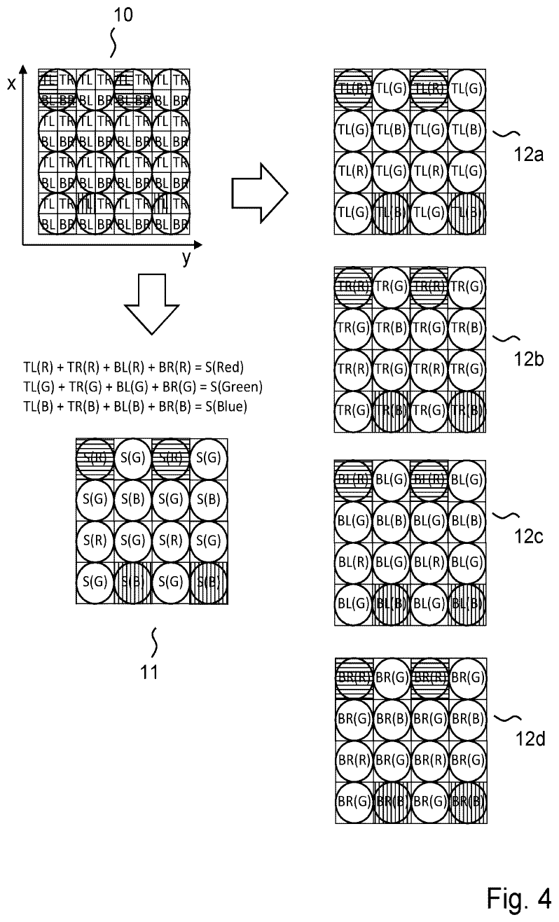

FIG. 4 presents an exemplary pixel matrix comprising a matrix of 4×4 pixel positions in the matrix. The pixel matrix represents the view of an raw image captured by the image sensor 1 or, as illustrated with the small section, a part of a larger view of an image. Each pixel position is related to one common lens element 7. Thus, a group of 2×2 light sensitive elements are placed behind a common lens element 7. There is a top row T and a bottom row B and a left column L and a right column R for each pixel position. The four light sensitive elements provides pixel values top-left (TL), top-right (TR), bottom-left (BL) and bottom-right (BR) for each sub-pixel position behind the common lens element 7 in a pixel position of the pixel matrix.

The image sensor 4 captures these sub-pixel values TL, TR, BL, BR for each image and provides the pixel matrix 10 comprising the set of sub-pixel values.

In step a1) the sub-pixel values related to a composition in the pixel matrix are combined to achieve a resulting combined pixel value per pixel position in the pixel matrix. For example, a sum-binned pixel matrix 11 is automatically processed by summing up the pixel values for each pixel position and related colour.

For example, the summed pixel values S(Red), S(Green) and S(Blue) are processed from the sub-pixel values TL (RGB), TR (RGB), BL (RGB) and BR (RGB) according to the following formulas:

$$TL ( R ) + T R ( R ) + B L ( R ) + B R ( R ) = S ( R )$$

$$TL ( G ) + T R ( G ) + B L ( G ) + B R ( G ) = S ( G )$$

$$TL ( B ) + T R ( B ) + B L ( B ) + B R ( B ) = S ( B )$$

with R=Red, G=Green and B=Blue.

Optionally, for other colours or white colour depending on the colour filter array, additionally combined pixel values S(colour) can be achieved.

The pixel matrix 11 represents the combined pixel values of the captured pixel matrix 10.

In addition, in a separate pre-processing stream, a plurality of sub-pixel matrixes 12a, 12b, 12c, 12d can be achieved.

Each of the number N of sub-pixel matrixes (N-focus images) comprises one specific sub-pixel value per pixel position of the pixel matrix 10 captured by the respective light sensitive element. Each pixel matrix 12a, 12b, 12c, 12d of the set is a sub-pixel matrix comprising sub-pixel values TL(colour), TR(colour), BR(colour), BL(colour) of a related set of light sensitive elements having the same relative position in the group of light sensitive elements for a common position in the pixel matrix related to a common lens element. Thus, the first sub-pixel matrix 12a comprises the sub-pixel values TL(colour) at the upper left position in the 2×2 sub-pixel matrix per pixel position. The second sub-pixel matrix 12b comprises the upper right sub-pixel values TR(colour), the third sub-pixel matrix 12c the bottom left sub-pixel values BL(colour) and the fourth sub-pixel matrix 12d the bottom right sub-pixel values BR(colour). The respective colour of the sub-pixel values depends on the filter element of the related lens element or optionally of the related sub-pixel light sensitive element.

The resulting set of sub-pixel matrixes 12a, 12b, 12c, 12d are pre-processed in the stream starting from step a2) in FIG. 2 independent from the combined pixel matrix 11 starting with step a1).

These different views of the same image contains different information. Performing such a separate and combined pre-processing enables better image quality of the resulting final image.

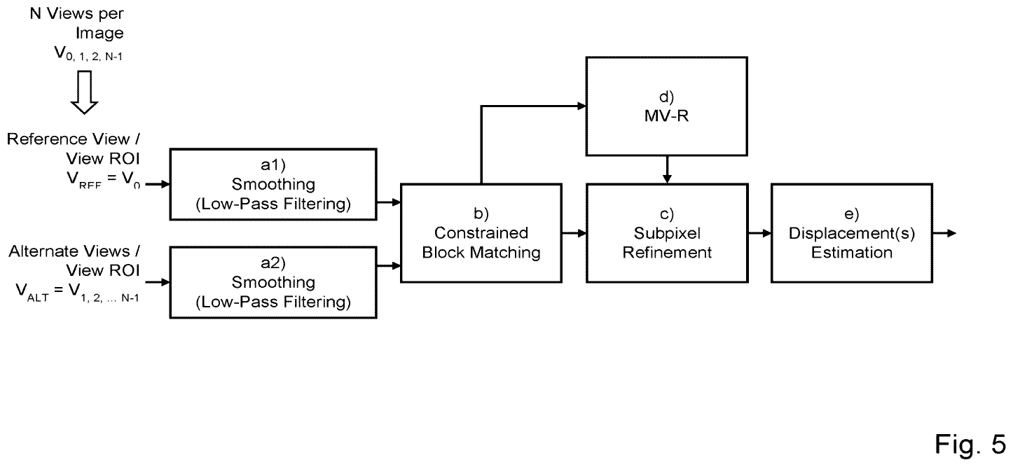

FIG. 5 presents a flow diagram of the method for processing image data of an image sensor 4 showing the pre-processing of the different views in more detail.

In step a1) the reference view V_{REF} is processed with a specific colour channel interpolation e.g. green-channel interpolation GCI. One of the N views V_{1, 2, . . . , N-1} of the image is selected as reference view. The reference view V_{REF} can be the TR view for example. In this example, the colour channel having the highest sampling or providing more details than the other channels is chosen for the reference view. In step b1) smoothing is taken place e.g. by low-path-filtering LPF.

The alternate views V_{ALT_1, 2, . . . , N-1} are processed in steps a2) separately from the reference view V_{REF} and separately from each other. A coloured channel interpolation CCI, e.g. a green channel interpolation GCI, is processed on the respective alternate view V_{ALT_1, 2, . . . , N-1}, =V₁; V₂; . . . ; V_{N-1}, e.g. TL, BL, BR views, with the related pixel matrixes.

The steps a1) and a2) may comprise smoothing, e.g by Low-Pass-Filtering. One purpose of smoothing is to robustify the estimation to noise.

Because of the position of the TR, TL, BL and BR views in the full-resolution raw data, the shift direction for the alternate views is known. This allows the simplification and speed up in the following step b) of Constrained Block Matching and restriction in the search direction.

This step b) is followed up by step c) of Sub-Pixel refinement using the result of a step d) of determining a Foreground and/or Background Map MV-R providing estimated motion model parameters. The motion model is translational.

Finally, Displacement(s) Estimation is processed in step e).

In the following, characteristics of OCL all-focus sensors are explained and based on those characteristics, the proposed image formation model is described in more detail. The model facilitates for example the disparity estimation, automatic focusing, demosaicing, multi-view fusion, and many other applications.

On-Chip-Lens (OCL) all-focus sensors have a unique design. A number (N) of sub-pixels with own photodiodes are housed beneath the same shared micro lens 7, and each of those photodiodes 14a, 14b can detect light and record the corresponding signal independently. The incident light through the OCL is split into N directions, resulting in N sub-aperture views of the scene captured simultaneously (see FIG. 5). In a sense, focus sensors act as a crude, N-view light-field camera.

To elaborate, in a dual-pixel OCL sensor, where the OCL is shared by two sub-pixels, for example left and right sub-pixels, the result is 2 views of the scene; left and right views, since the incident light is separated to the left and right directions.

Similarly, in a quad-pixel OCL sensor, where the OCL is shared by a 2×2 group of sub-pixels, the result is four views of the scene; top-left (TL), top-right (TR), bottom-left (BL) and bottom-right (BR) views, since the light is separated in those four directions, and so on and so forth. This is illustrated in FIG. 4 showing a 4×4 pixel matrix with 16 sub-pixels TL, TR, BL, BR of an 2×2 OCL All-Focus Sensor.

An OCL all-focus sensor could operate in different modes such as the native full-resolution mode, a remosaiced full-resolution mode, or binned version of either modes. As an example, the pixel matrices in FIG. 4 depict the sum-binned and focus image arrangements for a 2×2 OCL sensor with Quad-Bayer colour filter array (QB-CFA)).

A particular operation mode is selected for optimal performance under certain conditions, or to enable certain features. For example, in the sum-binned mode, the sub-pixels are merged into a bigger pixel with greater sensitivity, enabling better low-light performance.

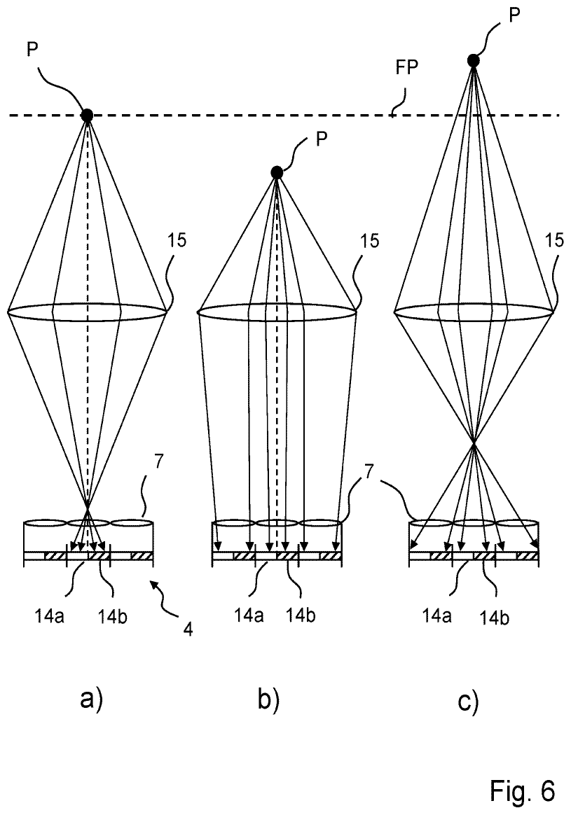

The disparity between the N sub-aperture views increases as the scene moves away from the focal plane, in either the forward or backward direction (in front of or behind the focal plane), as shown in FIG. 6. Hence, the signed uni/multi-directional disparity is derived from the multiple views (focus images), and is then used to calculate the optimal lens position for high-accuracy and high-speed auto-focusing. Typically focus images (or derived images from them) are thrown away by the camera hardware after calculating disparities. Based on the chosen operation mode for the intended feature or use case, the type of data that passes through the image signal processor is decided.

There are key characteristics that an OCL all-focus sensor could have/offer, irrespective of the specific sensor design in terms of the OCL, the sub-pixel colour filters and their arrangement, and the exposure settings. In fact, those characteristics can trigger sensor vendors to adopt advanced sensor design technologies that would allow new operation modes, which can enable differentiating features to the consumer market. In what follows, those characteristics are discussed, to set the stage for the proposed image formation model and the proposed image processing pipeline.

### 1. Inter-View Brightness Variation

Because the N views are captured by the same sensor, they should be synchronized temporally and spatially. However, the sub-pixels sharing a common lens element 7 (OCL) do not need to have the same exposure. They could have varying per-pixel exposure, for example, a Quad-Bayer Filter Array (QB-CFA) with two exposures, short and long. This is a technology commonly known as the digital overlap HDR (High-Density-Resolution) or DOL-HDR (Digital-Overlap-HDR). Due to the camera main lens shading effect and possibly the per sub-pixel exposure setting, the N views will experience inter-view brightness variation that would need to be taken into account (or even leveraged) in the image processing and fusion operations.

### 2. Varying Exposure in a Single Shot

Because of the split sub-pixel arrangement beneath the OCL, the incident light is split into multiple (N) directions. When the sub-pixels sharing the OCL have the same exposure, the exposure of the focus image is approximately 1/N-th of that of the sum-binned image. Here approximate is stated, because the split will not be perfect in real sensors. The result is an exposure value EV˜log 2(1/N) for the focus images; the focus images effectively will have less exposure than the sum-binned image, and saturated bright regions in the sum-binned image will not be saturated in the focus images. The sum-binned image and the set of focus images, therefore, can be viewed as images captured with two different exposures, with exposure value EV˜log 2(1/N), enabling HDR imaging from two exposures in a single shot. If M shots with M exposure times are captured by the OCL all-focus sensor, then the effective number of different EVs would be ˜2M, enabling HDR fusion from 2M exposures.

The above can be generalized to the case where the N sub-pixels have different exposures, such as the case highlighted above for Long and Short exposures. Hence, effectively, in a single capture, an OCL all-focus sensor could offer multiple differently-exposed images, with each image holding different information about the scene being photographed. Fusion of the single shot images (or images from multiple shots) could enable a variety of Computational Photography (CP) features, such as HDR, joint demosaicing and HDR, joint HDR and SR (Super Resolution), just to name a few possibilities.

### 3. Disparity as Blur Shift or Pixel Shift

Because the scene is optically blurred based on the distance from the focal plane, there is a shift or disparity between the N sub-aperture (focus) views, and that disparity depends on the depth and the shape of the blur kernel. The disparity between the N views can be modelled as explicit shift in the image content with sub-pixel accuracy. When the sub-pixels sharing the OCL have the same exposure (and white balancing), the shift estimation is simplified. In addition, because of the split-pixel arrangement, the disparity is directional, having a certain direction for certain views. That fact also simplifies the estimation of the shift, as the search direction is known. The search size for possible disparities depends on the scene depth and the shape of the blur kernel, but is relatively small, typically in the order of a few pixels.

For scene regions that are out of focus (far away from the focal plane, in either the forward or backward directions), the effective (defocus) blur will vary greatly between the views, and modelling disparity as explicit pixel shift would fail and lead to erroneous disparity estimation. In fact, it should be noted that it is the difference in the point spread functions (PSFs) of the sub-aperture views that produces disparity and not an explicit shift in image content.

### Disparity is a Result of PSF Difference

Without the loss of generality, let's consider the case of a 2×2 OCL all-focus sensor, such as the one that has a QB-CFA arrangement (QB=Quad Bayer). At a constant depth D, let H_{TL}, H_{TR}, H_{BL} and H_{BR} denote the point spread functions PSFs for the TL, TR, BL and BR views, respectively. Let X denote the unknown scene ROI with depth D. The four views can be expressed as

$${Y}_{T R} = X ⊗ {H}_{T R} + {η}_{n o i s e} \qquad ( 3 )$$

$${Y}_{T L} = X ⊗ {H}_{T L} + {η}_{n o i s e} \qquad ( 4 )$$

$${Y}_{B L} = X ⊗ {H}_{B L} + {η}_{n o i s e} \qquad ( 5 )$$

$${Y}_{B R} = X ⊗ {H}_{B R} + {η}_{n o i s e} \qquad ( 6 )$$

ηₙₒᵢₛₑ is the signal-dependent noise. Here it is assumed that the cross-talk and sensitivity and lens/colour shading corrections are performed. The inter-view horizontal and vertical disparities can then be expressed as

$${G}_{T R} - {G}_{T L} = X ⊗ ( {H}_{T R} - {H}_{T L} ) + {η}_{n o i s e} \qquad ( Horizontal Disparity \#1 ) ( 7 )$$

$${G}_{B R} - {G}_{B L} = X ⊗ ( {H}_{B R} - {H}_{B L} ) + {η}_{n o i s e} \qquad ( Horizontal Disparity \#2 ) ( 8 )$$

$${G}_{T R} - {G}_{B R} = X ⊗ ( {H}_{T R} - {H}_{B R} ) + {η}_{n o i s e} \qquad ( Vertical Disparity \#1 ) ( 9 )$$

$${G}_{T L} - {G}_{B L} = X ⊗ ( {H}_{T L} - {H}_{B L} ) + {η}_{n o i s e} \qquad ( Vertical Disparity \#2 ) ( 10 )$$

From the equations 7-10, it can be shown that, it is the difference in the inter-views PSFs of the sub-aperture views that produces disparity and not an explicit shift in image content.

When the N sub-pixels have different exposures, such as the case highlighted above for Long and Short exposures, disparity estimation would not only be expressed as pixel shift estimation and/or blur difference estimation, but also would include photometric shift estimation due to the varying exposure for the N sub-pixels, unless the brightness variation is accounted for prior to/in the disparity estimation algorithm. Regardless of the exposure being constant or varying for the sub-pixels sharing the OCL, the main lens shading will result in inter-view brightness variation, i.e. photometric shift between the views. This variation also needs to be accounted for prior to/in the disparity estimation solution.

The constrained displacement model as explained above is an example of the disparity estimation block in the pipeline. Based on the understanding of the blur characteristics, the displacement model can generalized easily for other types of sensors, e.g. OCL sensors providing more than four views (N>4).

### 4. Inter-View Blur Symmetry

When the scene is away from the focal plane, there will be a defocus blur. Because of the split sub-pixel arrangement, the defocus blur is split between the views, resulting in different point spread functions for the different views. The difference between the set of N point spread functions is what actually results in disparity, as mentioned earlier.

The point spread functions for the N views vary in a complex manner, and depend on several factors, such as the main lens focal length, the diameter of the aperture, the pixel angular response, the scene depth, the amount of defocus and the focus distance from the camera. That being said, those number N point spread functions will approximately exhibit a symmetry, thanks to the OCL and sub-pixel split design.

For example, for a dual-pixel OCL all-focus sensor, the point spread function of the left view will be approximately equal to the right view point spread function flipped about the vertical axis. And for a quad-pixel OCL all-focus sensor, the TL view point spread function PSF will be approximately equal to the BL view point spread function PSF flipped about the horizontal axis, and so on and so forth. The symmetry is only approximate, because of the imperfections in the positioning of the OCLs, the crosstalk between the sub-pixels, and other manufacturing limitations. The shape of the defocus blur and the N views point spread functions can be modelled parametrically, as a translating disk, a decaying Gaussian function or any other shape that could be derived from factory or laboratory calibrations. Regardless of the defocus blur model, its split into inter-symmetric (mirrored) point spread functions for the N views is a very useful cue that could enable a variety of Computational Photography features, such as reflection removal, veiling glare removal, defocus deblurring, SR, HDR, just to name a few examples.

### Disparity Estimation Block

In the following, the Disparity estimation block e) in FIG. 5 is explained in more detail by use of FIG. 6.

FIG. 6 presents a schematic diagram comprising a side view of the image sensor 4. One row of light sensitive elements are shown, wherein per row one pair of light sensitive elements 14a, 14b are placed adjacent to each other in a common row below a common lens element 7. One row of a pixel matrix comprises a plurality of lens elements 7 placed in a row adjacent to each other as visible and accordingly in a column as shown in FIG. 4.

Each lens element 7 is a micro lens integrally formed on the sensor chip of the image sensor 4.

The image camera 2 further comprises an optical lens system 15 comprising at least one lens (i.e. an objective).

The lens 15 has a related focal plane FP. The light beam starting from a point source of light P through the lens 15 depends on the position of the point source of light P relative to the focal plane FP.

At the left part a) of FIG. 6 the point source of light P lies on the focal plane FP. This results in focusing the light beam on one micro lens 7 and the related light sensitive elements 14a, 14b behind this common lens element 7. The distance between the object lens 15 and the focal plane FP corresponds to the distance of the object lens 15 and the plane of the lens elements 7 of the image sensor.

The middle part b) of FIG. 6 presents the situation where the point source of light P lies in a greater distance from the focal plane FP. This results in a focus of the light beam starting from the points of light P. So the object lens 15 is placed in front of the lens elements 7 between the plane of the lens element 7 and the object lens 15. Thus, the light beam is then widened and crosses a plurality of lens elements 7 and the related light sensitive elements 14a, 14b. It can be seen that the light beam is not equally distributed on all light sensitive elements 14a, 14b behind a common lens element. This depends on the incident angle of the light beam through the lens element 7.

The right view c) of FIG. 6 shows the situation where the point source of light P is behind the focal plane closer to the object lens 15. The focus of the object lens 15 lies then behind the image sensor so that the light beam passes a plurality of lens elements 7. The light sensitive elements 14a, 14b behind a common lens element are effected differently depending on the incident angle of the light beam through the respective lens element 7.

Depending from the focus of the image camera 4, i.e. the position of the point of source of light P with respect to the focal plane, a displacement of the image i.e. the sub-pixel values occurs.

For example, when each full-resolution frame can be separated into four views, top right (TR), top left (TL), bottom left (BL) and bottom right (BR) the pixel values TR, TL, BL, BR differ from each other depending on the displacement. One of the view, e.g. the TR view, can be set as a reference frame.

When the point source of light P is front of the focal plane the following sub-pixel level shift S occur. In the following, the shift from TR view is the reference view to the alternative views TL, BL and BR are listed:

| view | x-shift | y-shift |
|---|---|---|
| TL | +s | Almost negligible |
| BL | +s | −s |
| BR | Almost negligible | −s |

In case that the point source of light P is behind the focal plane, the sub-pixel level shift s from the reference view TR to the alternative views will be the following:

| view | x-shift | y-shift |
|---|---|---|
| TL | −s | Almost negligible |
| BL | −s | +s |
| BR | Almost negligible | +s |

The blur kernels act in opposite directions when the scene is in front of the focal plane or behind the focal plane. The direction of the blur itself being + or − is determined by the position of the view in the N subpixel grid, and the position of the scene with respect to the focal plane. Also, in the ideal case, the magnitude s is constant for the TL, BL and BR views, assuming perfect OCL symmetric positioning and no aberrations and no other sensor imperfections. This assumption is OK for calculating the disparity parameter s to a reasonable accuracy that is enough for moving the lens for automatic focusing, or for multi-view fusion, or remosaicing or any other processing that requires the knowledge of the disparity between the views.

Basically, the direction of the displacement of the view is known. For the 4-view OCL sensor (N=4), they are listed in the table. And so the search direction for s is known and can be constrained. This speeds up the computations. The explained model can generalized to any number and is not restricted to the exemplarily illustrated N=4 view OCL sensor. The method can also be applied accordingly for views N>4.

In the following, a proposed Image Formation Model is explained.

### The Proposed Image Formation Model

Now that some key characteristics of OCL all-focus sensors have been discussed, a generic image formation model is laid out in what follows. The purpose of the model is to serve as a basis for the order of operations in the image processing pipeline, and by extension a basis for the image processing/fusion algorithms; in particular to decide the requirements for processing images by a certain algorithm.

The following notations are used:
Yₙ: the n-th view (focus) raw image
Yₛᵤₘ: the sum-binned image for the N views
E_{n,m}: the colour-dependent exposure variation operator between the n-th and m-th view
C_{n,m}: the wavelength and colour-dependent crosstalk operator between the n-th and m-th view
Sₙ: the spatially-variant and colour-dependent lens shading operator for the n-th view
Hₙ(D): the PSF associated with the n-th view image at constant depth D
Fₙ: the colour-filter-array sub-sampling operator associated with the n-th view image
ηₙ: the signal-dependent noise for the n-th view

The summation H=Σₙ₌₁^{N}Hₙ(D) corresponds to the defocus blur kernel at constant depth D. The collection of PSFs, {Hₙ}ₙ₌₁^{N}, reasonably follow certain conditions
1. Non-negativity; Hₙ≥0
2. Inter-view symmetry
3. Equal inter-view contribution; ΣHₙ≈1/N if the defocus blur is isotropic.

Let X denote the unknown scene ROI with depth D. Following the notation above, at a given exposure time, the n-th view image can be expressed as

$${Y}_{n} = {F}_{n} ( {S}_{n} X ⊗ {H}_{n} ( D ) ) + {η}_{n} , n = 1 , 2 , … , N \qquad ( 1 )$$

$${Y}_{n} = {E}_{n , m} {C}_{n , m} {Y}_{m} , n = 1 , 2 , … , N , m \neq n \qquad ( 2 )$$

where ⊗ denotes the two-dimensional convolution operation. If the exposure is varying for the sub-pixels sharing the OCL, then the N views are related to each other by means of the exposure variation operation, which can be simplified to a linear operator, if the sensor is operating in the linear range. When all the views have the same exposure, this operator is unity. C_{n,m} captures the wavelength and colour-dependent crosstalk between the sub-pixels sharing the same OCL.

The proposed image formation model does not make any assumptions about the colour filters arrangement beneath the OCL; the sub-pixels sharing the same OCL can have similar or different colour filters. Also, the model does not limit the operation modes of an OCL all-focus sensor, e.g., with respect to the sub-pixel exposure settings, or type of binning.

### Constrained Multi-View Block Matching

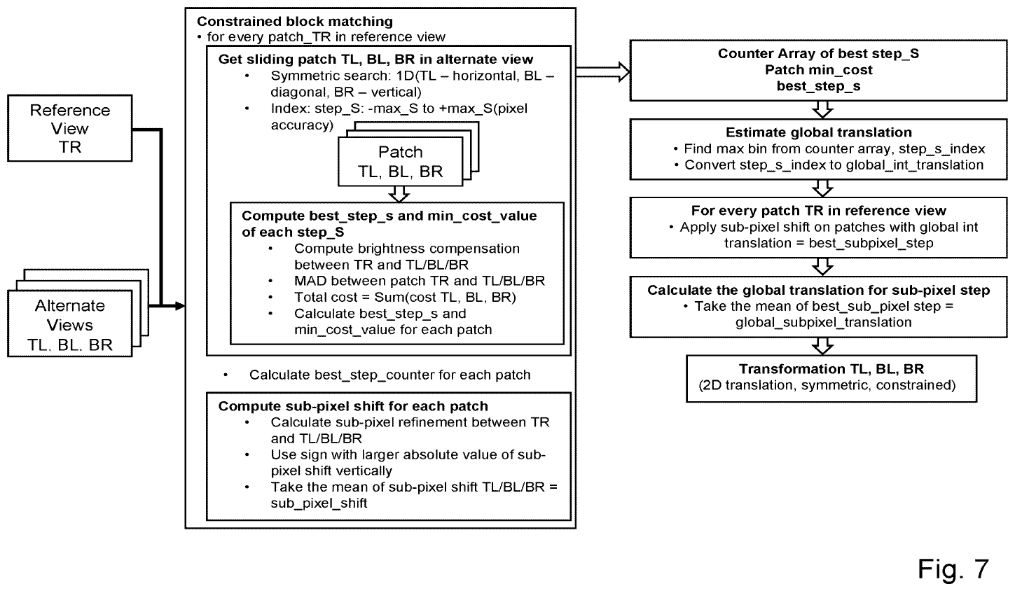

By use of the incoming Multi-Views or view region of interest (ROI) a constrained Multi-View block matching can be processed for not only precise registration but also enhancing the performance (see Step b) in FIG. 5). The output is the translational transformation from reference view to alternate views, with constant shift and symmetric signs in (sub-) pixel accuracy. A schematic diagram for the constrained Multi-View block matching is described in FIG. 7 and the following exemplary pseudocode:

```
A) Exemplary Pseudocode for Constrained Block Matching:
for each patch_TR in reference_frame do
  for each step_s in range from −max_S to +max_S do
    [patch_TL/BL/BR] = get_patch_position(step_s, patch_TR)
    [cost_TL/BL/BR] = compute_patch_cost(patch_TR, patch_TL/BL/BR)
    total cost = (cost_TL + cost_BL + cost_BR)
    [min_total_cost,  best_step_value,  compensated_patches_min_idx,  best_step_counter]  =
    calculate_best_step_s(total_cost, step_s)
  end for
  best_int_step(patch_TR) = best_step_value
  min_patch_cost(patch_TR) = min_total_cost
  [patch_subpixel_shift(idx_patch) = subpixel_refine(compensated_patches_min_idx)
end for
B) Pseudocode for Estimation of Translation:
[^{~,} best_step_index] = max(best_step_sounter);
Global_int_translation = (best_step_index − 1) − search_size;
for every_patch in reference_view do
  if global_int_translation == best_int_step(patch_TR)
  best_subpixel_step(patch_TR) = best_int_step(patch_TR) + patch_supixel_shift(idx_patch)
  end
end for
global_subpixel_translation = mean(best_subpixel_step);
```

Constrained block matching is based on the idea of block matching algorithm and it can run faster on a multi-view dataset because only one directional search of the blocks is necessary. This constrained block matching allows to register three views at the same time.

Before doing constrained block matching, Reference view TR and three other alternate views namely TL, BL and BR are interpolated through their main channels. At first, for each patch in the reference view—TR, sliding patches for TL, BL and BR in alternate views are calculated. One-dimension search is performed, for TL—only searching horizontally, for BL—only searching diagonally and for BR—only searching vertically.

For this symmetric search, only one loop for step_S from −max_S to max_S is used to compute co-ordinates of patch TL, BL and BR. The calculation of each alternative patch position is described as the following:

$$patch\_TL \_X = patch\_TR \_X - step\_s$$

$$patch\_TL \_Y = patch\_TR \_Y$$

$$patch\_BR \_X = patch\_TR \_X$$

$$patch\_BR \_Y = patch\_TR \_Y + step\_s$$

$$patch\_BL \_X = patch\_TR \_X - step\_s$$

$$patch\_BL \_Y = patch\_TR \_Y + step\_s ,$$

the sign of step_s is hard-coded in these formular and later the same sign of step_s is applied to form translational matrix. In Y direction, the sign of step_s is directly applied, and the opposite sign of step_s is applied in X direction.

To compute best_step_s, alter patches are compensated for the brightness changes with TR patch. Then, cost for each compensated alter patches TL/BL/BR for each step is calculated by the mean of absolute difference (MAD) between the reference patch TR and alter patch TL/BL/BR and patch costs are summarized to form total cost for each step. Finally, best_step_s and min_cost_value for each patch are calculated with respect to the minimum cost for all steps. For each patch from the reference frame TR, the number of best step—best_step_counter for each patch is counted and sub-pixel shifts for each patch with best_step_s are computed.

### Sub-Pixel Shift Sub-Block

For computing sub-pixel shift for each alter patch, Taylor Approximation algorithm is applied to calculate the sub-pixel refinement between TR and TL/BL/BR. The sign of sub-pixel shift is taken with respect to the larger absolute value of sub-pixel shift in the vertical direction. Finally, sub-pixel shift is calculated by the mean between x-shift of TL, y-shift of BR and x-shift and y-shift of BL.

### Estimate Integer Global Translation

Step s index—Steps_index is derived from counter array of best_step_s and then is converted to the global translation integer.

### Estimate the Best Subpixel Step

For each patch in the reference frame TR, best sub-pixel step is applied only where the patch has global integer translation and sub-pixel shift larger than one will not be taken into account.

### Calculate the Global Translation for Subpixel Step

The subpixel global translation is calculated by taking the mean of all best subpixel steps.

### Analysis of Computational Complexity

The complexity is presented here in terms of the big-O notation (O-notation), to provide an approximate prediction of the algorithm runtime as a function of the number of pixels to be processed.

| Parameter | Description |
|---|---|
| H × W | Size of the input frame/frame ROI; H = height, W = width |
| L × L | Size of the block matching square block; height = width = L |
| P | Block matching search size in pixels |
| A | The number of alter view is equal to 3 |

### Complexity Estimation for Constrained Multi-View Block Matching and Unconstrained Multi-View Block Matching

| Operation | Big O |
|---|---|
| Unconstrained Block Matching | $O ( \frac{A \times {( 2 \times P + 1 )}^{2}}{L \times L} \times H \times W )$ |
| Constrained Block Matching | $O ( \frac{A \times ( 2 \times P + 1 )}{L \times L} \times ( H - L - 2 * P ) \times ( W - L - 2 * P ) )$ |

From the table above, Constrained Block Matching can run faster than traditional global motion estimation using block matching algorithm.

### The Proposed Image Processing Pipeline

In the following, a proposed Image Processing Pipeline that follows the image formation model (based on the characteristics of OCL all-focus sensors) is explained. The image processing pipeline can be used for proper handling of the image data to maximize image quality, SW/HW efficiency, and enabling diverse features.

Based on the introduced image formation model, the order of operations in the image processing pipeline for handling OCL all-focus data for CP development is depicted below. It is worth mentioning that not all sensor operation modes are captured in this pipeline. The order of processing relevant to CP is of main interest. Also, the proposed data flow intends to maximize data sharing to reduce CPU cycles and minimize memory requirements. Some key operations are discussed in some details in what follows.

### A. Sensor Output Data

An OCL all-focus sensor delivers rich information content, which can enable a variety of CP features, in addition to the obvious benefit for automatic focusing. Typically the phase images (or their differences) are used for disparity estimation and are discarded by the camera hardware afterwards. However, the focus images enjoy unique features with respect to the non-phase sum-binned image(s), and utilizing them would enable a variety of computational photography features. Hence, in the proposed image processing pipeline, two data outputs from the all-focus sensor are:
1. The N focus (phase) images
2. The sum-binned image(s) (higher sensitivity, no phase information)

### B. 3A Control

The 3A (automatic exposure, automatic white balancing and automatic focusing) algorithms are key ones in the majority of modern consumer cameras. In the proposed image processing pipeline, the 3A statistics are calculated from the sensor raw data. In particular, the AE (automatic exposure) and AWB (automatic white balancing) algorithms use statistics calculated from either the sum-binned image(s) or the focus images. This approach will create the EV shift of ˜log 2(1/N) between the focus images and the sum-binned image(s). The same white balancing gains are applied to the sum-binned image(s) and focus images. The AF (automatic focusing) algorithm will utilize the statistics calculated from the uni/multi-directional disparity estimation algorithm, in order to decide on the optimal lens position for the focusing ROI.

In the case that the sub-pixels are allowed to have different exposures, the AE/AWB statistics can be calculated from one of the same-exposure sum-binned image(s) (e.g., the Long exposure or Short exposure sum-binned images) or the same-exposure focus images. Whatever the approach is, the EV shift will be observed between the sum-binned image(s) and the corresponding focus views.

### C. Pixel Data Pre-/Post-Processing

In addition to black-level correction, the sum-binned and focus images may need to be corrected for the crosstalk, because the separation between the sub-pixels under the OCLs will not be perfect, and the light passing through one sub-pixel might leak to the adjacent one. In addition, because of the main lens shading, not only the sum-binned image will experience colour lens shading, but also the N views will experience inter-view brightness variation due to the combined effect of lens shading and directional integration of light in different views (as discussed earlier). Lens shading correction is performed in order to compensate for the brightness variation in the sum-binned image(s) and the focus images. Image denoising (and defect pixel correction) in the raw domain is also performed. The image output from the CP engine is post-processed for colour correction, local/global tone mapping, sharpening and other image enhancement and colour rendering operations.

### D. Disparity and Depth Estimation

After the effect of lens shading is corrected for the N views (which manifests itself as colour-dependent brightness variation across the image), the inter-view uni/multi-directional disparity is calculated and used to provide statistics for the AF algorithm, in order to drive the lens movement for optimal focusing of the scene focusing ROI. From the estimated disparity, a depth map is constructed by the depth estimation block. The depth map is then utilized in the CP engine, to enable a number of features such defocus deblurring, synthetic bokeh, just to name a few examples.

### E. The Computational Photography Engine

In the proposed pipeline, the computational photography engine encompasses a collection of algorithms that operate on one or more of the following inputs
The estimated scene disparities
The estimated scene depth
The pre-processed sum-binned image(s)
The pre-processed focus images

And the engine output passes through the post-processing operations of colour correction and sharpening and contrast enhancement and other image enhancement operations. The CP engine can include (but is not limited to) the blocks depicted below. The details of those blocks depend largely on the underlying algorithmic design and are left for other independent disclosures.

The table below summarizes the possible input data for each of the CP blocks. There is a of course a dependency between the blocks; for example, image alignment is a key step for the success of several multi-image fusion features, such as HDR and SR. Some features can also be performed jointly. To avoid the complexity of presentation, the dependencies and possible joint operations are not depicted in the pipeline. The data flow through the CP sub-engines, however, should flexibly enable the dependent/joint features in a seamless manner. Also, data/memory sharing should always be performed to minimize CPU cycles and minimize hardware/memory cost.

It is worth noting from this table that the estimated disparities and depth as well as the focus images are valuable data that can enable a variety of CP features. Traditionally, the focus images were discarded by the camera hardware after disparity estimation, but in the proposed image processing pipeline they are used to the full.

Example List of Computational Photography Features and their Input Data

| Computational | Raw Sum- | Raw | Demosaiced | | | |
|---|---|---|---|---|---|---|
| Photography | Binned | Focus | Sum-Binned | Demosaiced | Estimated | Estimated |
| Block | Image(s) | Images | Image | Focus Images | Disparities | Depth |
| Raw Image | X | X | | | X | X |
| Demosaicing | | | | | | |
| Chroma | X | X | X | X | X | X |
| Denoising | | | | | | |
| Raw Image | X | X | | | X | X |
| Alignment | | | | | | |
| Colour Image | | | X | X | X | X |
| Alignment | | | | | | |
| Raw Image | X | X | | | X | |
| Super Resolution | | | | | | |
| Colour Image | | | X | X | X | X |
| Super Resolution | | | | | | |
| Single-Exposure | X | X | | | X | X |
| HDR | | | | | | |
| Multi-Exposure | X | X | | | X | X |
| HDR | | | | | | |
| Synthetic Bokeh | | | X | X | X | X |
| Dehazing | | | X | X | X | X |
| Defocus | X | X | X | X | X | X |
| Deblurring | | | | | | |
| Reflection | | | X | X | X | X |
| Removal | | | | | | |

The processing pipeline also implies certain sensor modes to be enabled, which are not in the current OCL all-focus sensors.

1. A method for processing image data of an image sensor, wherein the image sensor comprises a matrix of light sensitive elements and a plurality of lens elements and/or filter elements arranged in a pixel matrix in front of a finer sub-pixel matrix of light sensitive elements, wherein a group of light sensitive elements are placed behind a common lens element and/or a common filter element to provide sub-pixel values for a respective position in the pixel matrix, and wherein said image sensor is adapted to capture image data for a plurality of views, wherein each view comprises a matrix of a selected group of sub-pixel values of the pixel matrices captured by the matrix of light sensitive elements, the method comprising:
for each captured view of the image, determining first variations of sub-pixel values in the respective view separately from other views of the same image;
determining second variations of sub-pixel values related to the same position in the pixel matrix behind a respective lens element and/or filter element in a set of views of the same image; and
processing the image data for the image by use of the determined first and second variations.

2. The method according to claim 1, comprising automatically performing the operations on the captured raw image data by use of a generic image formation model expressing the n-th view image by the relations:
$${Y}_{n} = {F}_{n} ( {S}_{n} X ⊗ {H}_{n} ( D ) ) + {η}_{n} , with n = 1 , 2 , … , N ;$$
$$and$$
$${Y}_{n} = {E}_{n , m} {C}_{n , m} {Y}_{m} , with n = 1 , 2 , … , N , m \neq n ;$$
where Yₙ is the n-th view image pixel matrix, Fₙ is a color-filter-array sub-sampling operator associated with the n-th view image pixel matrix, Sₙ is a spatially-variant and color-dependent lens shading operator for the n-th view image pixel matrix determined as the first variations, X denotes an unknown scene region of interest with a focal depth, ⊗ denotes a two-dimensional convolution operation, Hₙ(D) is a point spread function associated with the n-th view image pixel matrix at a constant focal depth, ηₙ is a signal-dependent noise for the n-th view pixel matrix, E_{n,m} is a color-dependent exposure variation operator between the n-th and m-th view image pixel matrix determined as the second variations, and C_{n,m} is a wavelength and color-dependent crosstalk operator between the n-th and m-th view image pixel matrix determined as the second variations, wherein C_{n,m} captures the wavelength and color-dependent crosstalk between the sub-pixels of a common position in the pixel matrix sharing the same lens element and/or filter element.

3. The method according to claim 1, comprising
combining a set of views of an image by combining the plurality of sub-pixel values related to a common position in the pixel matrix, respectively, for each position in the matrix and pre-processing the combined sub-pixel values of the captured pixel matrix for an image;
separately pre-processing the views by pre-processing the captured pixel matrix with the plurality of sub-pixel values of a respective view by evaluating the variations between the sub-pixel values related to the same position in the matrix; and
joined pre-processing of both the pre-processed combined pixel values of the captured pixel matrix in the set of views and the pre-processed pixel matrix of the plurality of sub-pixel values for each position in the matrix for each view by use of the result of the evaluation of the variations.

4. The method according to claim 3, comprising combining the plurality of sub-pixel values related to a common position in the matrix by automatically processing the sum of the sub-pixel values related to the same position in the matrix to achieve a sum-binned pixel matrix.

5. The method according to claim 1, comprising combining the plurality of sub-pixel values related to a common position in the matrix, by automated processing the average of the sub-pixel values related to the same position in the matrix to achieve an average pixel matrix.

6. The method according to claim 1, comprising pre-processing the captured pixel matrix comprising the plurality of sub-pixel values per position in the pixel matrix by use of a set of pixel matrices, wherein each pixel matrix of the set is a sub-pixel matrix comprising sub-pixel values of a related set of light sensitive elements, each light sensitive element of the related set having the same relative position in the group of light sensitive elements for a common position in the pixel matrix related to a common lens element and/or a common filter element.

7. The method according to claim 1, comprising evaluating the variation of brightness of sub-pixel values related to the same pixel position in the set of views of an image.

8. The method according to claim 1, comprising evaluating a variation in exposure characteristics by correlating the combined views of an image with at least one view of the image, wherein the combined view comprising the combined pixel values each processed from the combination of related sub-pixel values for a respective position in the matrix represents a longer exposure time compared to the separate pixel matrices each comprising a matrix of sub-pixel values, and wherein said sub-pixel values each being captured by one respective light sensitive element.

9. The method according to claim 1, comprising evaluating a view blur by correlating related sub-pixel values of at least two views of the image, wherein a first sub-pixel matrix of a first group of sub-pixel values is correlated with a second sub-pixel matrix of a second group of sub-pixel values.

10. The method according to claim 9, comprising correlating the sub-pixel matrixes with each other by automatically processing the difference values for each of the positions in the matrix as difference of the sub-pixel value of one sub-pixel matrix of the set of sub-pixel matrices and the sub-pixel value of another sub-pixel matrix of the set of sub-pixel matrices.

11. The method according to claim 1, comprising automatically estimating a disparity between the views of an image, wherein the disparity of sub-pixel values related to the same pixel position is determined.

12. The method according to claim 1, comprising automatically estimating depth values of the captured image related to the focal depth of the captured image related to a focal plane of the image sensor.

13. An image processor unit for processing raw image data provided by an image sensor, said image sensor comprising a matrix of light sensitive elements and a plurality of lens elements and/or filter elements arranged in a pixel matrix in front of a finer sub-pixel matrix of light sensitive elements, wherein a group of light sensitive elements are placed behind a common lens element and/or a common filter element to provide sub-pixel values for a respective position in the pixel matrix, and wherein said raw image data comprising a matrix of pixel values for the pixel matrix captured by the matrix of light sensitive elements, said matrix of pixel values being divided in a set of views, each view comprising a matrix of sub-pixel values comprising a view specific sub-pixel of the sub-pixel matrix for each position in the matrix, which is related to a respective lens element and/or filter element, wherein the image processor unit is configured to:
determine, for each captured view of the image, of first variations of sub-pixel values in the respective view separately from other views of the same image;
determine second variations of sub-pixel values related to the same position in the pixel matrix behind a respective lens element and/or filter element in a set of views of the same image; and
process the image data for the image by use of the determined first and second variations.

14. (canceled)

15. A non-transitory computer readable medium comprising a computer program including instructions which, when the program is executed by a processing unit, causes the processing unit to carry out the steps of the method of claim 1.

16. The image processor unit according to claim 13, wherein the image processor unit is configured to automatically perform the operations on the captured raw image data by use of a generic image formation model expressing the n-th view image by the relations:
$${Y}_{n} = {F}_{n} ( {S}_{n} X ⊗ {H}_{n} ( D ) ) + {η}_{n} , with n = 1 , 2 , … , N ;$$
$$and$$
$${Y}_{n} = {E}_{n , m} {C}_{n , m} {Y}_{m} , with n = 1 , 2 , … , N , m \neq n ;$$
where Yₙ is the n-th view image pixel matrix, Fₙ is a color-filter-array sub-sampling operator associated with the n-th view image pixel matrix, Sₙ is a spatially-variant and color-dependent lens shading operator for the n-th view image pixel matrix determined as the first variations, X denotes an unknown scene region of interest with a focal depth, ⊗ denotes a two-dimensional convolution operation, Hₙ(D) is a point spread function associated with the n-th view image pixel matrix at a constant focal depth, ηₙ is a signal-dependent noise for the n-th view pixel matrix, E_{n,m} is a color-dependent exposure variation operator between the n-th and m-th view image pixel matrix determined as the second variations, and C_{n,m} is a wavelength and color-dependent crosstalk operator between the n-th and m-th view image pixel matrix determined as the second variations, wherein C_{n,m} captures the wavelength and color-dependent crosstalk between the sub-pixels of a common position in the pixel matrix sharing the same lens element and/or filter element.

17. The image processor unit according to claim 13, wherein the image processor unit is configured to:
combine a set of views of an image by combining the plurality of sub-pixel values related to a common position in the pixel matrix, respectively, for each position in the matrix and pre-processing the combined sub-pixel values of the captured pixel matrix for an image;
separately pre-process the views by pre-processing the captured pixel matrix with the plurality of sub-pixel values of a respective view by evaluating the variations between the sub-pixel values related to the same position in the matrix; and
performed joined pre-processing of both the pre-processed combined pixel values of the captured pixel matrix in the set of views and the pre-processed pixel matrix of the plurality of sub-pixel values for each position in the matrix for each view by use of the result of the evaluation of the variations.

18. The image processor unit according to claim 13, wherein the image processor unit is configured to combine the plurality of sub-pixel values related to a common position in the matrix by automatically processing the sum of the sub-pixel values related to the same position in the matrix to achieve a sum-binned pixel matrix.

19. The image processor unit according to claim 13, wherein the image processor unit is configured to combine the plurality of sub-pixel values related to a common position in the matrix, by automated processing the average of the sub-pixel values related to the same position in the matrix to achieve an average pixel matrix.

20. The image processor unit according to claim 13, wherein the image processor unit is configured to pre-process the captured pixel matrix comprising the plurality of sub-pixel values per position in the pixel matrix by use of a set of pixel matrices, wherein each pixel matrix of the set is a sub-pixel matrix comprising sub-pixel values of a related set of light sensitive elements, each light sensitive element of the related set having the same relative position in the group of light sensitive elements for a common position in the pixel matrix related to a common lens element and/or a common filter element.

21. The image processor unit according to claim 13, wherein the image processor unit is configured to evaluate the variation of brightness of sub-pixel values related to the same pixel position in the set of views of an image.
